(19) United States
(12) Patent Application Publication
(10) Pub. No.: US 2014/0354316 A1
(43) Pub. Date: Dec. 4, 2014

(54) CIRCUIT BOARD INSPECTION METHOD, CIRCUIT BOARD INSPECTION APPARATUS AND CIRCUIT BOARD INSPECTION TOOL

(71) Applicant: NIDEC-READ CORPORATION, Kyoto (JP)

(72) Inventor: Shinji Matsuoka, Kyoto (JP)

(73) Assignee: NIDEC-READ CORPORATION, Kyoto (JP)

(21) Appl. No.: 14/294,187

(22) Filed: Jun. 3, 2014

(30) Foreign Application Priority Data
Jun. 4, 2013 (JP) 2013-117746

(51) Int. Cl. G01R 31/28

(52) U.S. Cl. CPC G01R 31/2887; G01R 31/2884
USPC 324/750.24; 324/754.03

(57) ABSTRACT

There is provided a circuit board inspection tool configured to electrically connect a circuit board with a built-in electronic component and a circuit board inspection apparatus configured to inspect a plurality of wiring patterns formed on the circuit board. The circuit board inspection tool includes a plurality of contactors, an electrode body on which the respective contactors abut at the other end and which are electrically connected to the circuit board inspection apparatus, and a holding body having an inspection-side holding unit configured to guide one ends of the contactors to the inspection points and an electrode-side holding unit configured to guide the other ends thereof to the electrode units, wherein an amount of projection of a contactor which abuts on an inspection point of a wiring pattern conductively connected to the electronic component is formed to be greater than that of the other contactors.

### CROSS-REFERENCE TO RELATED APPLICATION

This application claims priority to Japanese Patent Application Serial No. 2013-117746, which was filed Jun. 4, 2013, and is incorporated herein by reference in its entirety.

### TECHNICAL FIELD

Various embodiments relate to a circuit board inspection method of performing electrical inspection of writing patterns formed on a circuit board or a substrate with a built-in electronic component (or IC, etc.), and a circuit board inspection tool and a circuit board inspection apparatus used in the circuit board inspection method.

### BACKGROUND

Currently, there has been widespread a circuit board with a built-in electronic component (or an embedded substrate) in which an electronic component including a diode and a capacitor is built. There are proposed various types of inspection methods of inspecting the circuit board with the built-in electronic component. For example, there are inspection methods as disclosed in Patent document 1 and Patent document 2. In the technologies disclosed in the Patent document 1 and the Patent document 2, there are disclosed a method of setting a test point to inspect the electronic component built in the circuit board.

By the way, in the actual inspection of the embedded substrate, test points (or inspection points) are set in wiring patterns formed on the surface of the circuit board, and contactors (or probes) conductively connected to a circuit board inspection apparatus are brought into contact with the inspection points to electrically connect the circuit board inspection apparatus and the wiring patterns. By this, electrical signals are transmitted or received. Thus, a circuit board inspection tool is used to electrically connect the embedded substrate and the circuit board inspection apparatus.

What is important in the case where the quality of the wiring pattern on the embedded substrate as described above is to perform the electrical inspection without damaging the electronic component built in the circuit board. In the case where the circuit board is inspected, an electric charge (or stray capacitance) of the circuit board is discharged to cause excess current, and there is a risk of damaging the electronic component built in the circuit board. In particular, the circuit board inspection apparatus configured to inspect the circuit board has such a problem that the excess current as described above easily occurs because the circuit board is mounted on an inspection table while the circuit board is floated with respect to a ground or an earth.

The following is a list of the aforementioned background art:
Japanese Patent Application Laid Open No. 2006-11507
Japanese Patent Application Laid Open No. 2009-276861

### SUMMARY

It is therefore an object of the present disclosure to provide a circuit board inspection method, a circuit board inspection apparatus and a circuit board inspection tool, which prevent the occurrence of the excess current due to the electric charge of the circuit board and which prevent the damage of the electronic component, in the case of inspecting the circuit board with the built-in electronic component, such as the embedded substrate.

An embodiment according to a clause 1 provides a circuit board inspection method of inspecting wiring patterns on a circuit board with a built-in electronic component by using a circuit board inspection apparatus configured to perform electrical inspection of the wiring patterns formed on the circuit board and a circuit board inspection tool configured to electrically connect the circuit board and the circuit board inspection apparatus, the circuit board inspection method provided with the steps of; grounding a wiring pattern electrically connected to the electronic component of the circuit board via the circuit board inspection tool; setting all the wiring patterns formed on the circuit board in conductive contact with the circuit board inspection apparatus via the circuit board inspection tool; and transmitting and receiving an electrical signal from the circuit board inspection apparatus, to and from the circuit board via the circuit board inspection tool, thereby performing the electrical inspection of the circuit board.

An embodiment according to a clause 2 provides the circuit board inspection method according to the clause 1, wherein after the electrical inspection is performed, the circuit board inspection tool is separated from the circuit board in a state in which all the wiring patterns are grounded by the circuit board inspection apparatus via the circuit board inspection tool.

An embodiment according to a clause 3 provides a circuit board inspection tool configured to electrically connect a circuit board with a built-in electronic component and a circuit board inspection apparatus configured to inspect a plurality of wiring patterns formed on the circuit board, the circuit board inspection tool provided with: a plurality of contactors which abut on inspection points on the wiring patterns, at one end; an electrode body having electrode units on which the respective contactors abut at the other end and which are electrically connected to the circuit board inspection apparatus; and a holding body having an inspection-side holding unit configured to guide one ends of the contactors to the inspection points and an electrode-side holding unit configured to guide the other ends of the contactors to the electrode units; wherein an amount of projection of a contactor which abuts on an inspection point of a wiring pattern conductively connected to the electronic component is formed to be greater than an amount of projection of the other contactors.

An embodiment according to a clause 4 provides the circuit board inspection tool according to the clause 3, wherein the amount of projection of the contact is set to be longer than the amount of projection of the other contactors, by a length which is the sum of a size accuracy amount of the contactors and a deflection amount of the circuit board.

An embodiment according to a clause 5 provides the circuit board inspection tool according to the clause 3 or 4, wherein the wiring pattern connected to the electronic component is connected to a GND terminal of the electronic component.

An embodiment according to a clause 6 provides a circuit board inspection apparatus configured to inspect a plurality of wiring patterns formed on a circuit with a built-in electronic component, the circuit board inspection apparatus provided with: a circuit board inspection tool according to the clause 3 or 4 for conductively connecting a wiring pattern of the circuit board as an inspection object and the circuit board inspection apparatus; a moving mechanism for making the circuit board inspection tool abut on the circuit board; an inspecting device for inspecting electrical characteristics of the wiring pattern; and a controlling device for controlling the moving mechanism and the inspecting device, wherein the controlling device activates the moving mechanism to make the circuit board inspection tool abut on the circuit board, and activates the inspecting device to ground the contactor which is in contact with the wiring pattern electrically connected to the electronic component.

According to the embodiment according to the clause 1 it is a circuit board inspection method of inspecting wiring patterns on a circuit board with a built-in electronic component by using a circuit board inspection apparatus configured to perform electrical inspection of the wiring patterns formed on the circuit board and a circuit board inspection tool configured to electrically connect the circuit board and the circuit board inspection apparatus. Firstly, a wiring pattern electrically connected to the electronic component of the circuit board is grounded via the circuit board inspection tool. Then, all the wiring patterns formed on the circuit board are set in conductive contact with the circuit board inspection apparatus via the circuit board inspection tool. Then, the electrical inspection of the circuit board is performed. It is thus possible to prevent the excess current due to the stray capacitance of the circuit board or the like from flowing into the electronic component and damaging the electronic component.

According to the embodiment according to the clause 2, after the electrical inspection is performed, the circuit board inspection tool is separated from the circuit board in a state in which all the wiring patterns are grounded via the circuit board inspection tool. It is thus possible to prevent the damage of the electronic component due to separation discharge which occurs in the case where the circuit board inspection tool is separated from the circuit board.

According to the embodiment according to the clause 3 it is a circuit board inspection tool configured to electrically connect a circuit board with a built-in electronic component and a circuit board inspection apparatus configured to inspect a plurality of wiring patterns formed on the circuit board, wherein an amount of projection of a contactor which abuts on an inspection point of a wiring pattern conductively connected to the electronic component is formed to be greater than an amount of projection of the other contactors. Thus, when the circuit board inspection tool grips the circuit board, firstly, the contactor having a large amount of projection abuts on the circuit board as the inspection object. It is thus possible to prevent the excess current, which damages the electronic component, from flowing into the electronic component.

According to the embodiment according to the clause 4, the amount of projection of the contact is set to be longer than the amount of projection of the other contactors, by a length which is the sum of a size accuracy amount of the contactors and a deflection amount of the circuit board. Thus, when the circuit board inspection tool grips the circuit board, this contactor certainly abuts on the inspection point before the other contacts do.

According to the embodiment according to the clause 5, the wiring pattern connected to the electronic component is connected to a GND terminal of the electronic component. It is thus possible to protect the electronic component from the excess current, more certainly.

According to the embodiment according to the clause 6, it is a circuit board inspection apparatus configured to inspect a plurality of wiring patterns formed on a circuit with a built-in electronic component, the circuit board inspection apparatus provided with: a circuit board inspection tool according to the clause 3 or 4 for conductively connecting a wiring pattern of the circuit board as an inspection object and the circuit board inspection apparatus; a moving mechanism for making the circuit board inspection tool abut on the circuit board; an inspecting device for inspecting electrical characteristics of the wiring pattern; and a controlling device for controlling the moving mechanism and the inspecting device, wherein the controlling device activates the moving mechanism to make the circuit board inspection tool abut on the circuit board, and activates the inspecting device to ground the contactor which is in contact with the wiring pattern electrically connected to the electronic component. Thus, in the case where the circuit board is gripped by the circuit board inspection tool, it is possible to prevent the excess current due to the stray capacitance of the circuit board or the like from flowing into the electronic component and damaging the electronic component.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 is a schematic cross sectional view illustrating an embodiment of a circuit board as an inspection object of the present disclosure;

FIG. 2 is a cross sectional view of a schematic side view illustrating a circuit board inspection apparatus of the present disclosure;

FIG. 3 is a schematic side view illustrating a circuit board inspection tool of the present disclosure; and

FIG. 4 is a schematic enlarged view illustrating a dashed-line portion a of the circuit board inspection tool illustrated in FIG. 3.

### DETAILED DESCRIPTION

The following detailed description refers to the accompanying drawing that show, by way of illustration, specific details and embodiments in which the disclosure may be practiced.

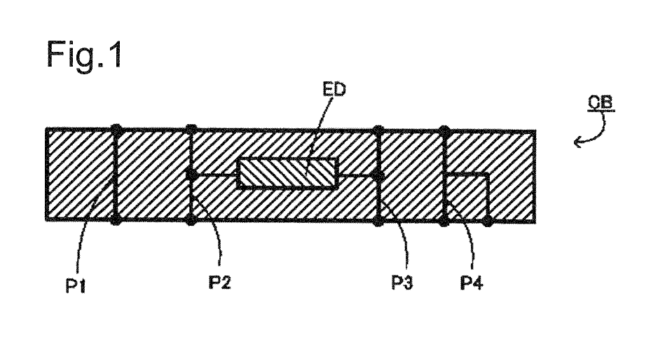

A circuit board or a substrate as an inspection object of the present disclosure will be briefly explained. FIG. 1 is a schematic cross sectional view illustrating the circuit board as the inspection object of the present disclosure. The circuit board as the inspection object of the present disclosure is a circuit board referred to a so-called embedded substrate, and is characterized in that an electronic component is built inside the circuit board. In a circuit board CB illustrated in FIG. 1, four wiring patterns P (P1 to P4) and an electronic component ED are illustrated, and a wiring pattern P2 and a wiring pattern P3 are connected to the electronic component ED. The wiring pattern P2 is conductively connected to a GND terminal of the electronic component ED.

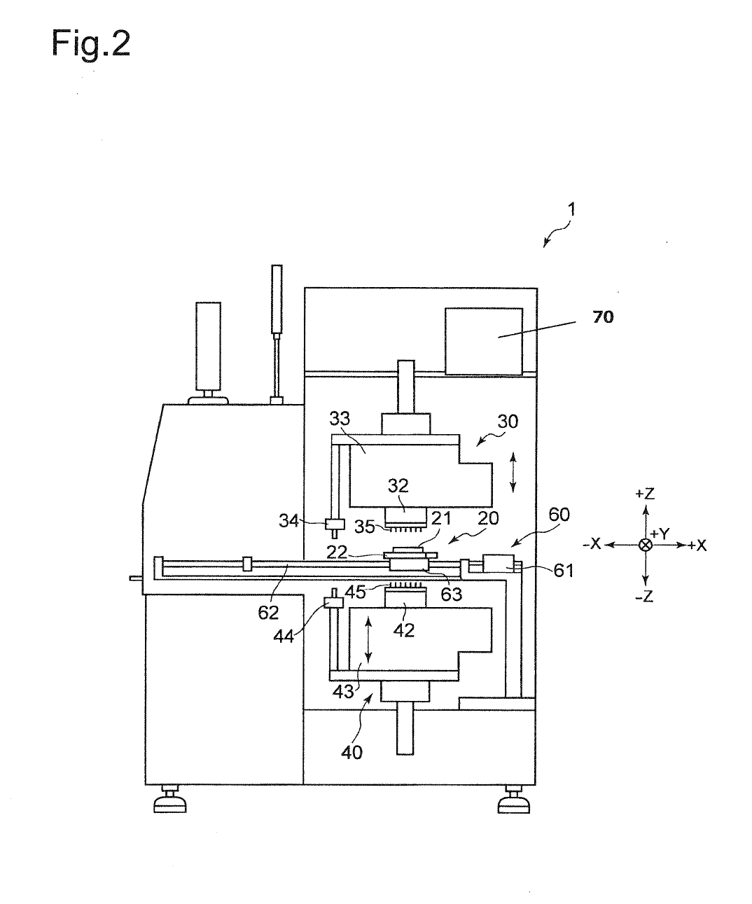

Next, a circuit board inspection apparatus 1 for inspecting the circuit board used in the present disclosure will be briefly explained. FIG. 2 is a structural cross sectional view illustrating a circuit board inspection apparatus 1 in an embodiment of the present disclosure. FIG. 2 illustrates a rectangular coordinate system using XYZ axes, from the viewpoint of clarifying moving directions of a conveying table 20 and first and second inspection tool moving units 30 and 40. The Y axis has a positive direction which is directed from the front side to the back side of the paper of FIG. 1.

The circuit board inspection apparatus 1 is provided with a circuit board moving unit 60 for moving the conveying table 20 along the X axis, and the first and second inspection tool moving units 30 and 40 for moving, in a YZ surface, inspection tools 32 and 42 on which a plurality of probes (or contactors) 35 and 45 for circuit board inspection are mounted. The first and second inspection tool moving units 30 and 40 are arranged symmetrically with respect to a XY surface. The details of the inspection tools will be explained later, and the inspection tools will have reference numerals of 32 and 42 in the explanation of the configuration of the circuit board inspection apparatus 1.

The conveying table 20 is provided with a circuit board holding unit 22 for mounting an inspection circuit board 21 thereon, and a cylinder bracket 63 fixed on a bottom surface of the inspection circuit board 21. The cylinder bracket 63 has a screw hole formed, wherein the screw hole pierces through the cylinder bracket 63 in a longitudinal direction.

The circuit board moving unit 60 is provided with a ball screw 62 configured to engage with the screw hole of the bracket 63, and a drive unit 61 configured to rotate the ball screw 62. The screw thread and the thread groove on the ball screw 62 are not illustrated for simplification. If the ball screw 62 is rotated by the drive unit 61, the amount of movement and the moving directions along the X axis of the bracket 63, i.e. the conveying table 20, are determined depending on the amount and the direction of rotation of the ball screw 62.

The first inspection tool moving unit 30 is provided with an inspection tool holding unit 33. The inspection tool holding unit 33 functions as holding the inspection tool 32 on which the plurality of probes 35 for circuit board inspection are mounted, and functions as moving the inspection tool 32 to make the plurality of probes 35 for circuit board inspection abut on inspection points of wires as the inspection objects on the inspection circuit board 21. The plurality of probes 35 for circuit board inspection and the like are electrically connected to a scanner (not illustrated) for inspecting and measuring the circuit board, via the inspection tool holding unit 33.

The second inspection tool moving unit 40 is provided with an inspection tool holding unit 43, as in the inspection tool holding unit 33 of the first inspection tool moving unit 30. The inspection tool holding unit 43 functions as in the inspection tool holding unit 33.

The movement of the first and second inspection tool moving units 30 and 40 and the circuit board moving unit 60 is controlled by a control apparatus (not illustrated) of the circuit board inspection apparatus 1. The first and second inspection tool moving units 30 and 40 have main cameras 34 and 44 installed, respectively, in order to specify the positions of the inspection circuit board 21 (or a sheet substrate B) and the conveying table 20.

The circuit board inspection apparatus 1 has an inspecting device 70 for performing the electrical inspection of the circuit board CB. The inspecting device 70 has a configuration necessary for the electrical inspection of the circuit board CB. For example, the inspecting device 70 has an electric power supply unit (not illustrated) configured to perform continuity or conduction inspection of a wiring pattern, a detection unit (not illustrated) configured to detect an electrical signal from the wiring pattern, a determination unit (not illustrated) configured to process and determine a detected signal from the detection unit, a change unit or a switching unit (not illustrated) configured to change a conduction pathway from a contactor, to each unit, and the like. The inspecting device 70 can be configured, for example, by adopting a direct current or alternating current power supply, an ammeter, a voltmeter, a switching element, and the like.

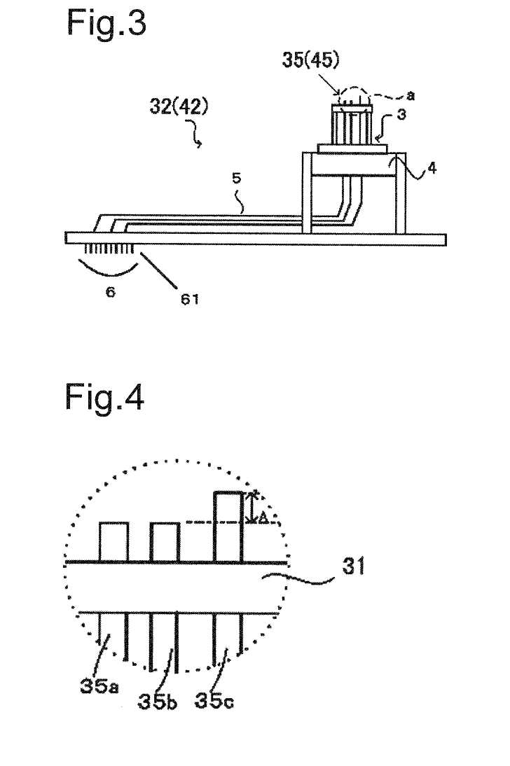

Next, the inspection tool 32 or 42 used on the circuit board inspection apparatus 1 will be explained. FIG. 3 illustrates an embodiment of the circuit board inspection tool. The inspection tool 32 has the plurality of contactors 35 or 45, a holding body or a support body 3 configured to hold the contactors in a multi-needle manner, an electrode body 4 having electrode units configured to support the holding body 3 and configured to be in contact with the contactors 35 to be conductive to the circuit board inspection apparatus 1, a conducting wire unit 5 extended from and electrically connected to the electrode units, and a connection body 6 having connecting units 61 electrically connected to the circuit board inspection apparatus 1. FIG. 3 is a schematic side view for explaining the outline of the circuit board inspection tool 32. FIG. 3 illustrates three contactors 35, but the number of the contactors 35 is not particularly limited to this example.

Each of the contactors 35 electrically connects the inspection point set in the wiring pattern P and respective one of the electrode units described later. The contactor 35 abuts on the inspection point at one end, and abuts on the electrode unit at the other end. Due to the contactor 35, the inspection point and the electrode unit are electrically connected. The contactor 35 is formed, for example, in an elongated rod shape, and can adopt a member having conductivity and flexibility. Moreover, the contactor 35 can also adopt a member using a spring which extends and contracts in the longitudinal direction.

The electrode body 4 holds the electrode units (not illustrated) on which the contactors 35 abut at the other end and which are electrically connected to the circuit board inspection apparatus 1. The electrode units are formed to be substantially flush with the surface of the electrode body 4. Each of the electrode unit is preferably formed to be slightly greater than an outer diameter of respective one of the contactors 35.

The conducting wire unit 5 electrically connects the electrode units of the electrode body 4 and the connecting units 61 of the connection body 6 described later. The conducting wire unit 5 is only required to electrically connect the electrode units 41 and the connecting units 61, and can adopt a linear metal wire such as, for example, a copper wire.

If the conducting wire unit 5 is prepared by using the metal wire, the electrode body 4 is provided with through holes to place respective conducting wires in the through holes, and the conducting wires are cut to be flush with the surface of the electrode body 4. By this, the electrode units can be formed. In this case, one ends of the metal wires function as the electrode units, and the other ends of the metal wires are conductively connected to the connecting units 61.

The connection body 6 holds the connecting units 61 electrically connected to the circuit board inspection apparatus 1. Each of the connecting units 61 is conductively connected to a connection point of the circuit board inspection apparatus 1, thereby being electrically connected to the circuit board inspection apparatus 1. The connection can adopt, for example, connector connection formed in an uneven shape (or in a concave and convex shape)

The holding body 3 holds the contactors 35, guides one ends of the contactors 35 to the inspection points and guides the other ends of the contactors 35 to the electrode units. The holding body 3 in FIG. 3 is formed of two plate-like members disposed at a predetermined interval, and can bend the contactors 35 in a space formed by the two plate-like members.

FIG. 4 is a partial enlarged view illustrating the circuit board inspection tool illustrated in FIG. 3. The embodiment in FIG. 4 illustrates a state of the contactors 35 projecting from a plate-like member 31 on the upper side of the holding body 3. The circuit board inspection tool 3 in FIG. 4 has a contactor 35c which abuts on the inspection point on the wiring pattern conductively connected to the electronic component ED, a contactor 35a and a contactor 35c which abut on the inspection points on the wiring patterns not conductively connected to the electronic component ED.

In the circuit board inspection tool 32, the amount of projection of the contactor 35c which abuts on the inspection point of the wiring pattern P conductively connected to the electronic component ED is formed to be greater than the amount of projection of the other contactors 35a and 35b (refer to FIG. 4). Thus, if the circuit board inspection apparatus 1 moves the circuit board inspection tool 32, the contactor 35c firstly abuts on the inspection point of the circuit board CB. After that, the contactors 35a and 35b abut on the inspection points of the circuit board CB.

The amount of projection of the contactor 35c which abuts on the wiring pattern P conductively connected to the electronic component ED is set to be longer than the amount of projection of the other contactors 35a and 35b, by a length A which is the sum of a size accuracy amount of the contactors 35 and a deflection amount of the circuit board. Due to the formation of the contactor 35c to be longer by the length A, in the case where the circuit board inspection tool 32 grips the circuit board CB, the contactor 35c can certainly abut on the circuit board CB before the other contactors 35 do, because the contactor 35c projects by the length A.

In the circuit board inspection tool 32, as described above, the contactor 35c which abuts on the inspection point of the wiring pattern P conductively connected to the electronic component ED is disposed to be longer (or to project) by the length A; however, the contactor 35c set to be longer by the length A can be also set in the wiring pattern P which is connected to the GND terminal of the electrode component ED. Due to the setting of the contactor 35c in the wiring pattern P which is connected to the GND terminal of the electrode component ED, the damage of the electronic component ED can be prevented, more certainly.

The above is the explanation of the configuration of the circuit board inspection apparatus and the inspection tool of the present disclosure.

Next, the circuit board inspection method of the present disclosure will be explained.

Firstly, the circuit board CB as the inspection object is set. At this time, the contactor 35 which abuts on the inspection point set in the wiring pattern P conductively connected to the electronic component ED of the circuit board CB as the inspection object is specified. The specified contactor 35 is set such that the amount of projection from the plate-like member of the holding body 3 is longer by a predetermined length A than that of the contactors 35 which abut on the inspection points set in the wiring patterns P not conductively connected to the electronic component ED (or the other contactors 35). The upper-side circuit board inspection tool 32 and the lower-side circuit board inspection tool 42 are prepared depending on the inspection points of the circuit board CB.

If the circuit board CB as the inspection object is prepared on the circuit board inspection apparatus 1, the inspection is started. The circuit board CB is gripped by the upper-side circuit board inspection tool 32 and the lower-side circuit board inspection tool 42. At this time, in the upper-side circuit board inspection tool 32 or the lower-side circuit board inspection tool 42, the capacitor 35 or 45 which abuts on the wiring pattern P (or the wiring pattern P2 in FIG. 1) conductively connected to the electronic component ED is formed to be longer by the predetermined length A. Incidentally, in the case of the circuit board CB in FIG. 1, four contactors 35 are disposed in the upper-side circuit board inspection tool 32, and five contactors 35 are disposed in the lower-side circuit board inspection tool 42. Here, the contactor which abuts on the wiring pattern P2 connected to the GND terminal of the electronic component ED is disposed to project by the length A.

The circuit board inspection apparatus 1 moves each of the upper-side circuit board inspection tool 32 and the lower-side circuit board inspection tool 42 to abut on the surface of the circuit board CB. At this time, the circuit board inspection apparatus 1 performs switching to ground the contactor 35 or 45 connected to the wiring pattern P2 connected to the electronic component ED. Thus, the contactors abut on the circuit board CB in a grounded state.

Moreover, in the upper-side circuit board inspection tool 32 or the lower-side circuit board inspection tool 42, the contactor 35 or 45 conductively connected to the electronic component ED firstly abuts on the inspection point of the circuit board CB. At this time, even if there is stray capacitance in the circuit board CB itself, electricity is discharged from the circuit board inspection apparatus 1 via the circuit board inspection tool 32 or 42, and the damage of the electronic component ED of the circuit board ED can be thus prevented. The circuit board inspection apparatus 1 moves the upper-side circuit board inspection tool 32 and the lower-side circuit board inspection tool 42 until the circuit board CB can be gripped (or until all the contactors abut on the inspection points).

If the circuit board inspection apparatus 1 sets each of the upper-side circuit board inspection tool 32 and the lower-side circuit board inspection tool 42 on the circuit board CB, the electrical inspection is performed on each of the wiring patterns P.

If the electrical inspection ends, all the wiring patterns P of the circuit board CB are grounded by the circuit board inspection apparatus 1 via the circuit board inspection tool 32 or 42, and in this state, the circuit board inspection apparatus 1 moves the upper-side circuit board inspection tool 32 and the lower-side circuit board inspection tool 42 to be separated from the circuit board CB. As described above, due to the movement of the circuit board inspection apparatus 1, it is possible to prevent the damage of the electronic component ED due to the occurrence of the excess current caused by the separation discharge which occurs in the case where the circuit board inspection tools are separated from the circuit board.

As described above, in the present disclosure, it is possible to protect the electronic component ED from the discharge caused by that the circuit board inspection tools abutting on and being separated from the circuit board CB, and it is possible to prevent the damage of the electronic component ED by the inspection.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

### DESCRIPTION OF REFERENCE NUMERALS

1 circuit board inspection apparatus
32 (42) circuit board inspection tool
35 (45) contactor
A predetermined length
CB circuit board

What is claimed is:

1. A circuit board inspection method of inspecting wiring patterns on a circuit board with a built-in electronic component by using a circuit board inspection apparatus configured to perform electrical inspection of the wiring patterns formed on the circuit board and a circuit board inspection tool configured to electrically connect the circuit board and the circuit board inspection apparatus, said circuit board inspection method comprising:
grounding a wiring pattern electrically connected to the electronic component of the circuit board via the circuit board inspection tool;
setting all the wiring patterns formed on the circuit board in conductive contact with the circuit board inspection apparatus via the circuit board inspection tool; and
transmitting and receiving an electrical signal from the circuit board inspection apparatus, to and from the circuit board via the circuit board inspection tool, thereby performing the electrical inspection of the circuit board.

2. The circuit board inspection method according to claim 1, wherein after the electrical inspection is performed, the circuit board inspection tool is separated from the circuit board in a state in which all the wiring patterns are grounded by the circuit board inspection apparatus via the circuit board inspection tool.

3. A circuit board inspection tool configured to electrically connect a circuit board with a built-in electronic component and a circuit board inspection apparatus configured to inspect a plurality of wiring patterns formed on the circuit board, said circuit board inspection tool comprising:
a plurality of contactors which abut on inspection points on the wiring patterns, at one end;
an electrode body having electrode units on which the respective contactors abut at the other end and which are electrically connected to the circuit board inspection apparatus; and
a holding body having an inspection-side holding unit configured to guide one ends of the contactors to the inspection points and an electrode-side holding unit configured to guide the other ends of the contactors to the electrode units; wherein
an amount of projection of a contactor which abuts on an inspection point of a wiring pattern conductively connected to the electronic component is formed to be greater than an amount of projection of the other contactors.

4. The circuit board inspection tool according to claim 3, wherein the amount of projection of the contact is set to be longer than the amount of projection of the other contactors, by a length which is the sum of a size accuracy amount of the contactors and a deflection amount of the circuit board.

5. The circuit board inspection tool according to claim 3, wherein the wiring pattern connected to the electronic component is connected to a GND terminal of the electronic component.

6. A circuit board inspection apparatus configured to inspect a plurality of wiring patterns formed on a circuit with a built-in electronic component, said circuit board inspection apparatus comprising:
a circuit board inspection tool for conductively connecting a wiring pattern of the circuit board as an inspection object and the circuit board inspection apparatus;
said circuit board inspection tool comprising:
a plurality of contactors which abut on inspection points on the wiring patterns, at one end;
an electrode body having electrode units on which the respective contactors abut at the other end and which are electrically connected to the circuit board inspection apparatus; and
a holding body having an inspection-side holding unit configured to guide one ends of the contactors to the inspection points and an electrode-side holding unit configured to guide the other ends of the contactors to the electrode units; wherein
an amount of projection of a contactor which abuts on an inspection point of a wiring pattern conductively connected to the electronic component is formed to be greater than an amount of projection of the other contactors. a moving mechanism for making the circuit board inspection tool abut on the circuit board;
an inspecting device for inspecting electrical characteristics of the wiring pattern; and
a controlling device for controlling the moving mechanism and the inspecting device, wherein
the controlling device activates the moving mechanism to make the circuit board inspection tool abut on the circuit board, and activates the inspecting device to ground the contactor which is in contact with the wiring pattern electrically connected to the electronic component.
